(19) United States
(12) Patent Application Publication
(10) Pub. No.: US 2009/0014717 A1
(43) Pub. Date: Jan. 15, 2009

(54) TEST IC STRUCTURE

(75) Inventors: Chien-Li Kuo, Hsinchu (TW); Ping-Chang Wu, Hsinchu County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/776,095

(22) Filed: Jul. 11, 2007

(51) Int. Cl. H01L 23/58

(52) U.S. Cl. 257/48; 257/E21.524

(57) ABSTRACT

A test IC structure is described, which is disposed in a scribe line region of a wafer and includes first and second test keys, first and second conductive plugs, first and second test pads, and a passivation layer over the scribe line region. The first/second test key includes a first/second active device and a first/second interconnect structure electrically connected thereto, wherein the second test key is arranged substantially parallel with the first one. The first/second plug is disposed over the first/second interconnect structure and contacts with the upmost metal layer thereof. The first/second test pad is disposed over the first and the second test keys and contacts with the first/second conductive plug. The passivation layer has therein a first opening exposing a portion of the first test pad and a second opening exposing a portion of the second test pad.

### BACKGROUND OF THE INVENTION

1. Field of Invention

This invention relates to an integrated circuit (IC) structure used for a circuit test, and more particularly to a test IC structure that allows the ratio of space utilization of the scribe line region to be increased.

2. Description of Related Art

After the IC fabricating process on a wafer is finished but before the wafer is cut into dies, a wafer acceptance test (WAT) is usually conducted to derive the product yield. Prior to the WAT, some test keys and test pads electrically connected thereto have been formed in the scribe lines around a die. The test keys are electrically connected to an external circuit or probes of a probe card via the test pads to check the quality of the IC process in the WAT. A device formed in a die is usually for logic computation or for memory, while a similar device is also formed in the scribe line as a part of the test key.

FIG. 1A illustrates a top view of a wafer (100) after its IC process is finished, and FIG. 1B is a locally magnified view of a scribe line region 110 in FIG. 1A. The wafer 100 includes a 2D-array of dies 102 separated by scribe lines 104. The exemplary test key 106 is disposed in the scribe line region 110, while an array of test pads 108 are disposed over the test key 106. The width of a scribe line 104 may be 62 μm, the size of a test pad 108 may be 54×54 μm², and the pitch “d” between the test pads 108 may be 100 μm. Moreover, the test devices are disposed under regions 112 between the test pads 108 but not under the test pads 108. A passivation layer (not shown) is usually formed over the wafer to protect the integrated circuits on the wafer from moisture and/or other contaminants. The passivation layer has therein multiple pad openings 114, each exposing a portion of a test pad 108a and possibly having a size of 52×52 μm².

Accordingly, only about a half of the scribe line region is disposed with test pads in the conventional test IC structure, so that the ratio of space utilization of the scribe line region is lower and the manufacturing cost is higher. Moreover, since the current fabricating process does not allow the pitch of the test pads to be further decreased and numerous test keys have to be disposed, the width of the scribe line must be increased to two, three or more times for accommodating all the test keys. Consequently, less dies are divided from a wafer so that the manufacturing cost is increased.

Since the current IC fabricating process limits the ratio of space utilization in the scribe lines and increases the manufacturing cost, a new test IC structure that can solve such a problem is highly desired.

### SUMMARY OF THE INVENTION

Accordingly, this invention provides a test IC structure, which allows more test keys to be disposed in the scribe line region to increase the ratio of space utilization in the scribe line region and lower the manufacturing cost.

The test IC structure of this invention is disposed in a scribe line region of a wafer and includes first and second test keys, first and second conductive plugs, first and second test pads and a passivation layer over the scribe line region. The first test key includes a first active device and a first interconnect structure electrically connected thereto. The second test key is arranged substantially parallel with the first test key and includes a second active device and a second interconnect structure electrically connected thereto. The first conductive plug is disposed over the first interconnect structure and contacts with the upmost metal layer thereof. The second conductive plug is disposed over the second interconnect structure and contacts with the upmost metal layer thereof. The first test pad is disposed over the first and second test keys and contacts with the first conductive plug. The second test pad is disposed over the first and second test keys and contacts with the second conductive plug. The passivation layer has therein a first opening exposing a portion of the first test pad and a second opening exposing a portion of the second test pad.

In an embodiment, the width of the first test key is equal to that of the second test key, and the total width of the first and second test keys is substantially equal to the width of the scribe line region.

In an embodiment, the above test IC structure further includes a dielectric layer between the first and second test keys and the first and second conductive plugs.

In an embodiment, the first and the second active devices are the same kind of device. In another embodiment, the first and the second active devices are different kinds of devices.

In addition, the first and second conductive plugs may include aluminum (Al). The first and the second test pads may include Al. The upmost metal layers of the first and the second interconnect structures may include copper (Cu).

In some embodiments, the test IC structure further includes at least one third test key, a third conductive plug and a third test pad. The third test key is arranged substantially parallel with the first and second test keys and between them, and includes a third active device and a third interconnect structure electrically connected thereto. The third conductive plug is disposed over the third interconnect structure and contacts with the upmost metal layer thereof. The third test pad is disposed over the first to third test keys and contacts with the third conductive plug. The passivation layer further has a third opening therein that exposes a portion of the third test pad.

In an embodiment, the widths of the first, the second and the third test keys are the same, and the total width of the first to third test keys is substantially equal to the width of the scribe line region.

In an embodiment, the first to third active devices are the same kind of device. In another embodiment, the first to third active devices are different kinds of devices.

In addition, the third conductive plug and the third test pad may also include Al, and the upmost metal layers of the third interconnect structure may also include copper.

Another test IC structure of this invention is also disposed in a scribe line region of a wafer, including a first test key, a second test key arranged substantially parallel with the first test key, a first conductive plug, a second conductive plug, a first test pad, a second test pad and a passivation layer over the scribe line region. The first conductive plug is disposed over the first test key and contacts with the upmost metal layer of the same. The second conductive plug is disposed over the second test key and contacts with the upmost metal layer of the same. The first test pad is disposed over the first and the second test keys and contacts with the first conductive plug. The second test pad is disposed over the first and second test keys and contacts with the second conductive plug. The passivation layer has a first opening exposing a portion of the first test pad and a second opening exposing a portion of the second test pad.

In an embodiment, the width of the first test key is equal to that of the second test key, and the total width of the first and the second test keys is substantially equal to the width of the scribe line region.

In an embodiment, the above test IC structure further includes a dielectric layer between the first and second test keys and the first and second conductive plugs.

In addition, the first and the second conductive plugs may include aluminum. The first and the second test pads may include aluminum. The upmost metal layers of the first and the second test keys may include copper.

In some embodiments, the test IC structure further includes at least one third test key arranged substantially parallel with the first and second test keys and between them, a third conductive plug, and a third test pad. The third conductive plug is over the third test key and contacts with the upmost metal layer thereof. The third test pad is over the first to third test keys and contacts with the third plug. The passivation layer further has a third opening therein that exposes a portion of the third test pad.

In an embodiment, the widths of the first, the second and the third test keys are the same, and the total width of the first, the second and the third test keys is substantially equal to the width of the scribe line region.

In addition, the first, the second and the third conductive plugs may include aluminum. The first, the second and the third test pads may include aluminum. The upmost metal layers of the first, the second and the third test keys may include copper.

As mentioned above, in the test IC structure of this invention, the active devices are disposed under the test pads, and the first and the second test keys are arranged substantially in parallel under the test pads and respectively electrically connected to the first and the second test pads via the first and the second conductive plugs respectively. Hence, the number of test key in the scribe line region is increased to increase the ratio of space utilization and lower the manufacturing cost. Moreover, as the fabricating process allows narrower test keys to be formed, the test IC structure may even include three or more test keys in the scribe line region.

In order to make the aforementioned and other objects, features and advantages of the present invention comprehensible, a preferred embodiment accompanied with figures is described in detail below.

### BRIEF DESCRIPTION OF THE DRAWINGS

FIG. 1A illustrates a top view of a wafer after its IC process is finished.

FIG. 1B is a locally magnified view of the scribe line region 110 in FIG. 1A.

FIG. 2 illustrates a top view of a test IC structure according to an embodiment of this invention.

### DESCRIPTION OF EMBODIMENTS

It is noted that the following embodiment is intended to further explain this invention but not to limit the scope of the same.

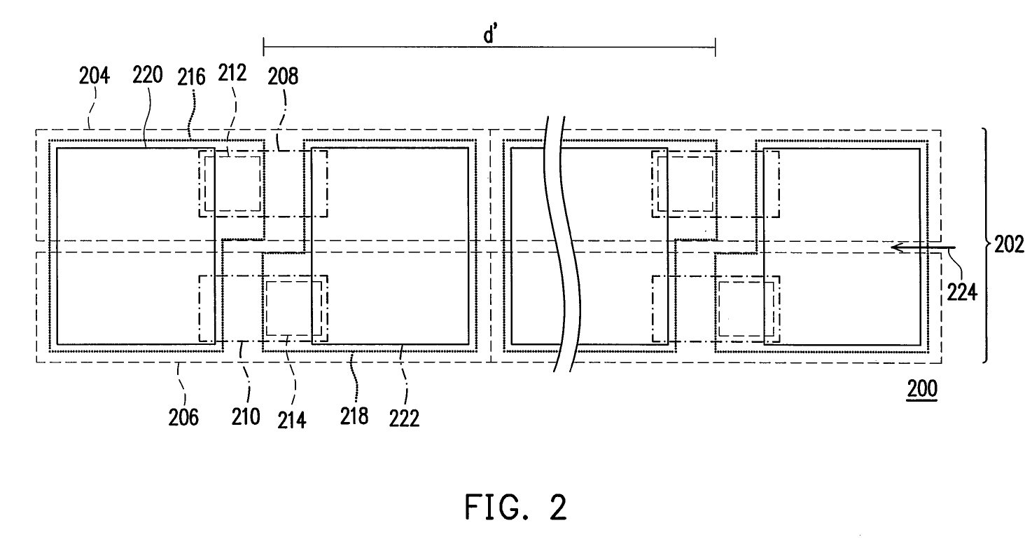

FIG. 2 illustrates a top view of a test IC structure according to the embodiment. Though the size and the pitch of each part of the test IC structure are according to the current fabricating process in the case of FIG. 2, they are not limited to those illustrated.

Referring to FIG. 2, the wafer/substrate 200 includes a plurality of dies (not sown) on which active devices and interconnect structures are formed, and scribe line regions 202 in which similar active devices and interconnect structures are formed to serve as test keys. The fabricating process of active devices and interconnect structures in the scribe line region 202 is usually integrated with that in the dies. The active devices in the scribe line region 202 may be transistors or other semiconductor devices, and the interconnect structure in the scribe line region 20 may include a stack of multiple metal layers and conductive plugs to electrically connect with the same active devices.

The test IC structure in this embodiment is disposed in a scribe line region 202 of the wafer/substrate 200, including a first test key 204 and second test key 206 arranged substantially parallel with the first test key 204. That is, the first test key 204 and the second test key 206 have substantially the same extension direction and are disposed in parallel. The first test key 204 mainly includes a first active device (not shown) and a first interconnect structure electrically connected thereto that includes an upmost metal layer 208. The second test key 206 includes a second active device (not shown) and a second interconnect structure electrically connected thereto that includes an upmost metal layer 210. The first and the second active devices are omitted in FIG. 2 because they are known in the prior art. It is noted that the first and second active devices may be the same kind of device or be different kinds of devices. The material of the upmost metal layers 208 and 210 may be copper.

Moreover, the width of the first test key 204 may be equal to that of the second test key 206, and the total width of the first and second test keys 204 and 206 may be substantially equal to the width of the scribe line region 202. The width of the scribe line region 202 may be 62 μm, and that of the first or second test key 204 or 206 may be 30 μm. In such cases, each of the upmost metal layers 208 and 210 has a width smaller than 30 μm and may have a size of 30×20 μm² (length×width).

The test IC structure further includes a first conductive plug 212 and a second conductive plug 214 arranged in parallel. The first conductive plug 212 is over the interconnect structure of the first test key 204 and contacts with the upmost metal layer 208 thereof. The second conductive plug 214 is over the interconnect structure of the second test key 206 and contacts with the upmost metal layer 210 thereof. The material of the conductive plugs 212 and 214 may be Al. In an example, each of the first and second conductive plugs 212 and 214 has a size of 14×18 μm². Moreover, a dielectric layer (not shown) may be further disposed between the first and second test keys 204 and 206 and the first and second conductive plugs 212 and 214. The dielectric layer may include a low-k material.

In addition, a first test pad 216 is disposed over both of the first and the second test keys 204 and 206 and contacts with the first conductive plug 212, and a second test pad 218 is disposed over both of the first and the second test keys 204 and 206 and contacts with the second conductive plug 214. The material of the first test pad 216 and the second test pad 218 may be Al. In this embodiment, the pitch d′ between the first test pads 216 or the second test pads 218 may be 100 μm. It is particularly noted that this embodiment adopts the so-called BOAC (bond on active circuit) technique and disposes the active devices of the test IC structure under the test pads. Meanwhile, the first and second test keys 204 and 206 are disposed in parallel under the array of the test pads 216 and 218, and the first test pads 216 and second test pads 218 are respectively electrically connected to the first test key 204 and the second test key 206 via the first conductive plugs 212 and the second conductive plugs 214 respectively. Accordingly, the number of test keys in a conventional scribe line region can be increased to increase the ratio of space utilization in the scribe lines as well as lower the manufacturing cost.

Moreover, a passivation layer (not shown) may be further formed over the wafer/substrate 200 to protect the underlying integrated circuits from external moisture and/or other contaminants. A portion of the passivation layer is located over the scribe line region 202, having therein a first opening 220 exposing a portion of the first test pad 216 and a second opening 222 exposing a portion of the second test pad 218, wherein the openings 220 and 222 both are called “pad openings”. The passivation layer may include silicon oxide, silicon nitride, silicon oxynitride or other suitable insulator.

Accordingly, even with conventional fabricating steps, scribe line width and test pad pitch, applying this invention can still increase the number of test keys allowable in the scribe line regions. Thereby, the space utilization ratio in the scribe line regions is increased and the manufacturing cost is lowered thereby.

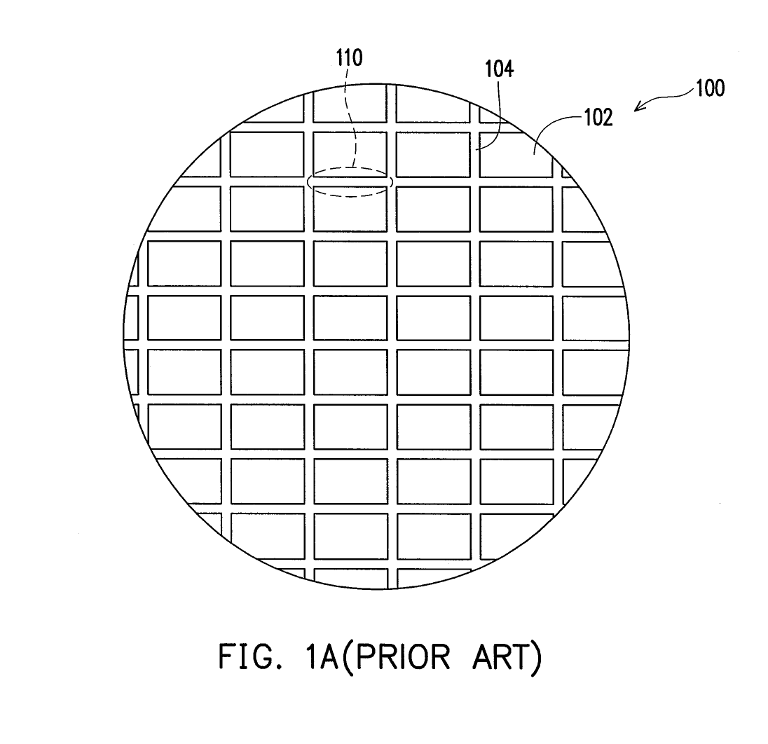

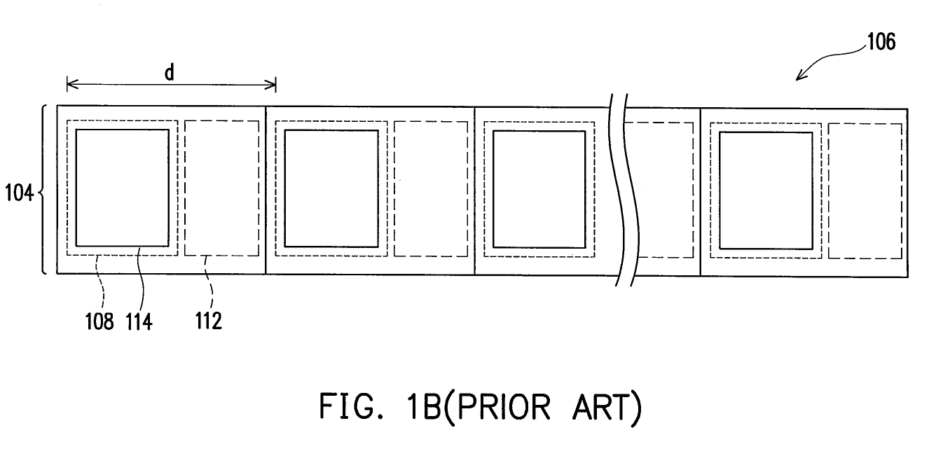

It is also noted that the conventional test IC structure as show in FIGS. 1A-1B easily suffers from cracks and delamination at the interfaces between different material layers, through which external moisture easily intrude the circuit to lower the reliability thereof or even make devices fail. However, since the test IC structure of the invention includes interconnect structures 208 and 210 as metal layers at both sides of the saw path (e.g., 224 in FIG. 2) in the scribe line region 202 and the first and the second conductive plugs 212 and 214 serve as supporting structures that enhance the strength, such damages can be prevented. Moreover, if allowed by the fabricating steps, dummy patterns like metal patterns may be further included as supporting structures.

On the other hand, since the probes of the probe card are made contact with the test pads in the WAT, the positions of the test pads have to be identified first. To easily identify the positions, the test pads may have different shapes or the conductive plugs have letter/numeral-like shapes to indicate the positions. The identification method is well known to one of ordinary skill in the prior art and is therefore omitted here.

In addition, though the above test IC structure is designed based on the current fabricating steps and includes only two test keys in parallel, the test IC structure of this invention can still be modified in the future as more advanced fabricating processes are provided. For example, the test IC structure may further include at least one third test key (not shown). That is, the test IC structure may include three or more test keys.

Taking a case where three test keys are disposed as an example, the third test key is arranged substantially parallel with the first and second test keys 204 and 206 and between the first and second test keys 204 and 206. The width of the third test key may be equal to that of the first or second test keys 204 or 206, and the total width of the three test keys may be substantially equal to the width of the scribe line region 202. For example, when the width of the scribe line region 202 is 62 μm, each of the first test key 204, the second test key 206 and the third test key may be about 20 μm.

The third test key mainly includes a third active device and a third interconnect structure electrically connected thereto, similar to the case of the first or second test key 204 or 206. A third conductive plug is disposed over the third interconnect structure and contacts with the upmost metal layer thereof. The material of the third conductive plug may be Al, and that of the upmost metal layer of the third interconnect structure may be Cu. In addition, the third test pad is disposed over the first test key 204, the second test key 206 and the third test key and contacts with the third conductive plug. The material of the third test pad may also be Al. Moreover, the passivation layer further has a third opening therein that exposes a portion of the third test pad. The active device in the third test key can be the same kind of device or a different kind of device as compared with the first and second active devices.

This invention has been disclosed above in the preferred embodiments, but is not limited to those. It is known to persons skilled in the art that some modifications and innovations may be made without departing from the spirit and scope of this invention. Hence, the scope of the present invention should be defined by the following claims.

What is claimed is:

1. A test IC structure, disposed in a scribe line region of a wafer and comprising:
a first test key, comprising a first active device and a first interconnect structure electrically connected to the first active device;
a second test key, arranged substantially parallel with the first test key and comprising a second active device and a second interconnect structure electrically connected to the second active device;
a first conductive plug, disposed over the first interconnect structure and contacting with an upmost metal layer of the first interconnect structure;
a second conductive plug, disposed over the second interconnect structure and contacting with an upmost metal layer of the second interconnect structure;
a first test pad, disposed over the first and the second test keys and contacting with the first conductive plug;
a second test pad, disposed over the first and the second test keys and contacting with the second conductive plug; and
a passivation layer over the scribe line region, having therein a first opening exposing a portion of the first test pad and a second opening exposing a portion of the second test pad.

2. The test IC structure of claim 1, wherein a width of the first test key is equal to a width of the second test key, and a total width of the first and the second test keys is substantially equal to a width of the scribe line region.

3. The test IC structure of claim 1, further comprising a dielectric layer between the first and second test keys and the first and second conductive plugs.

4. The test IC structure of claim 1, wherein the first and second active devices are the same kind of device.

5. The test IC structure of claim 1, wherein the first and second active devices are different kinds of devices.

6. The test IC structure of claim 1, wherein the first and the second conductive plugs comprise aluminum.

7. The test IC structure of claim 1, wherein the first and the second test pads comprise aluminum.

8. The test IC structure of claim 1, wherein the upmost metal layers of the first and the second interconnect structures comprise copper.

9. The test IC structure of claim 1, further comprising:
at least one third test key, arranged substantially parallel with the first and the second test keys and between the first and the second test keys, and including a third active device and a third interconnect structure electrically connected to the third active device;
a third conductive plug, disposed over the third interconnect structure and contacting with an upmost metal layer of the third interconnect structure; and
a third test pad, disposed over the first, the second and the third test keys and contacting with the third conductive plug;
wherein the passivation layer further has a third opening therein that exposes a portion of the third test pad.

10. The test IC structure of claim 9, wherein widths of the first, the second and the third test keys are the same, and a total width of the first, the second and the third test keys is substantially equal to a width of the scribe line region.

11. The test IC structure of claim 9, wherein the first, the second and the third active devices are the same kind of device.

12. The test IC structure of claim 9, wherein the first and second active devices are different kinds of devices.

13. The test IC structure of claim 9, wherein the first, the second and the third conductive plugs comprise aluminum.

14. The test IC structure of claim 9, wherein the first, the second and the third test pads comprise aluminum.

15. The test IC structure of claim 9, wherein the upmost metal layers of the first, the second and the third interconnect structures comprise copper.

16. A test IC structure, disposed in a scribe line region of a wafer and comprising:
a first test key;
a second test key arranged substantially parallel with the first test key;
a first conductive plug, disposed over the first test key and contacting with an upmost metal layer of the first test key;
a second conductive plug, disposed over the second test key and contacting with an upmost metal layer of the second test key;
a first test pad, disposed over the first and the second test keys and contacting with the first conductive plug;
a second test pad, disposed over the first and the second test keys and contacting with the second conductive plug; and
a passivation layer over the scribe line region, having therein a first opening exposing a portion of the first test pad and a second opening exposing a portion of the second test pad.

17. The test IC structure of claim 16, wherein a width of the first test key is equal to a width of the second test key, and a total width of the first and the second test keys is substantially equal to a width of the scribe line region.

18. The test IC structure of claim 16, further comprising a dielectric layer between the first and second test keys and the first and second conductive plugs.

19. The test IC structure of claim 16, wherein the first and the second conductive plugs comprise aluminum.

20. The test IC structure of claim 16, wherein the first and the second test pads comprise aluminum.

21. The test IC structure of claim 16, wherein the upmost metal layers of the first and the second test keys comprise copper.

22. The test IC structure of claim 16, further comprising:
at least one third test key, arranged substantially parallel with the first and the second test keys and between the first and the second test keys;
a third conductive plug, disposed over the third test key and contacting with an upmost metal layer of the third test key; and
a third test pad, disposed over the first, the second and the third test keys and contacting with the third conductive plug;
wherein the passivation layer further has a third opening therein that exposes a portion of the third test pad.

23. The test IC structure of claim 22, wherein widths of the first, the second and the third test keys are the same, and a total width of the first, the second and the third test keys is substantially equal to a width of the scribe line region.

24. The test IC structure of claim 22, wherein the first, the second and the third conductive plugs comprise aluminum.

25. The test IC structure of claim 22, wherein the first, the second and the third test pads comprise aluminum.

26. The test IC structure of claim 22, wherein the upmost metal layers of the first, the second and the third test keys comprise copper. _
